(19) United States
(12) Patent Application Publication
(10) Pub. No.: US 2026/0164587 A1
(43) Pub. Date: Jun. 11, 2026

(54) GAS VALVE CABINET AND ELECTRICAL CONTROL BOX

(71) Applicant: Apex Union Technologies CO., LTD., Taipei City (TW)

(72) Inventor: CHENG-PU HSIEN, Hsinchu County (TW)

(21) Appl. No.: 19/269,011

(22) Filed: Jul. 14, 2025

(30) Foreign Application Priority Data
Dec. 10, 2024 (TW) 113147762

(51) Int. Cl. H05K 7/14; F16K 27/00; G08C 17/02

(52) U.S. Cl. CPC H05K 7/1467; F16K 27/00; G08C 17/02; H05K 7/1481

(57) ABSTRACT

A gas valve cabinet and an electrical control box. The gas valve cabinet includes an electrical control box and a gas valve box. The electrical control box includes a first box unit, a plurality of control units, a plurality of substrate units and a wireless communication unit. The wireless communication unit is disposed on the first box unit and connected to the control unit. The gas valve box includes a second box unit, a plurality of pipe units and a plurality of sensing units. The sensing units are disposed on the pipe units and connected to at least one control unit for detecting the flow rate or pressure of the gas transmitted by one of the pipe units to generate at least one sensing signal. The at least one wireless communication unit is configured to transmit at least one sensing signal to at least one external device.

### CROSS-REFERENCE TO RELATED PATENT APPLICATION

This application claims the benefit of priority to Taiwan Patent Application No. 113147762, filed on December 10, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a gas valve cabinet and an electrical control box, and more particularly to a gas valve cabinet with wireless transmission function, and an electrical control box with wireless transmission function.

### BACKGROUND OF THE DISCLOSURE

In the related art, the electrical control part of the gas distribution supply equipment is connected to external electronic equipment through cables. Therefore, not only is the equipment construction cost high, but also the location of the equipment is limited.

### SUMMARY OF THE DISCLOSURE

In response to the above-referenced technical inadequacy, the present disclosure provides a gas valve cabinet and an electrical control box.

In order to solve the above-mentioned problems, one of the technical aspects adopted by the present disclosure is to provide a gas valve cabinet, which includes an electric control box and a gas valve box. The electric control box includes a first box unit having a first accommodating space, a plurality of control units disposed in the first accommodating space, a plurality of substrate units respectively connected to one of the control units, and at least one wireless communication unit disposed on the first box unit and connected to at least one of the control units. The gas valve box includes a second box unit having a second accommodating space and adjacent to the first box unit; a plurality of pipe units disposed in the second accommodating space, in which at least one of the pipe units passes through the second box unit; and a plurality of sensing units disposed on the pipe units and connected to at least one of the control units, in which each of the sensing units is configured to detect a flow rate or a pressure of a gas transmitted by one of the pipe units to generate at least one sensing signal. The at least one wireless communication unit is configured to transmit the at least one sensing signal to at least one external device.

In one of the possible or preferred embodiments, the first box unit has a plurality of outer surfaces, the first accommodating space is defined by the outer surfaces, and the at least one wireless communication unit is disposed on one of the outer surfaces. Each of the control units is a programmable logic controller. The at least one wireless communication unit is an external antenna component using fifth generation mobile communication technology.

In one of the possible or preferred embodiments, the outer surfaces include a top surface, a bottom surface, a front side surface, a rear side surface, a left side surface and a right side surface, the top surface is connected to the front side surface, the rear side surface, the left side surface and the right side surface and is disposed opposite to the bottom surface, the front side surface is connected to the top surface, the bottom surface, the left side surface and the right side surface and is disposed opposite to the rear side surface, and the left side surface is connected to the top surface, the bottom surface, the front side surface and the rear side surface and is disposed opposite to the right side surface. The at least one wireless communication unit is disposed on one of the top surface, the bottom surface, the front side surface, the rear side surface, the left side surface and the right side surface.

In one of the possible or preferred embodiments, the electric control box further includes: a plurality of driving units disposed in the first accommodating space and connected to one of the control units, and a plurality of valve units disposed in the second accommodating space and respectively connected to the pipe units, in which the valve units are connected to the driving units, and each of the valve units is configured to control one of the pipe units for transmitting the gas.

In one of the possible or preferred embodiments, the electric control box further includes: a human-machine interface unit disposed on the first box unit and connected to at least one of the control units, in which the human-machine interface unit is configured to generate and transmit at least one processing command to at least one of the control units by touch; and a wired communication unit connected to at least one of the control units, and at least one external device.

In order to solve the above-mentioned problems, another one of the technical aspects adopted by the present disclosure is to provide an electric control box, which includes a box unit having an accommodating space, a plurality of control units disposed in the accommodating space, and a plurality of substrate units respectively connected to one of the control units.

In one of the possible or preferred embodiments, the box unit has a plurality of outer surfaces, the accommodating space is defined by the outer surfaces, and the at least one wireless communication unit is disposed on one of the outer surfaces.

In one of the possible or preferred embodiments, the outer surfaces include a top surface, a bottom surface, a front side surface, a rear side surface, a left side surface and a right side surface, the top surface is connected to the front side surface, the rear side surface, the left side surface and the right side surface and is disposed opposite to the bottom surface, the front side surface is connected to the top surface, the bottom surface, the left side surface and the right side surface and is disposed opposite to the rear side surface, and the left side surface is connected to the top surface, the bottom surface, the front side surface and the rear side surface and is disposed opposite to the right side surface. The at least one wireless communication unit is disposed on one of the top surface, the bottom surface, the front side surface, the rear side surface, the left side surface and the right side surface.

In one of the possible or preferred embodiments, each of the control units is a programmable logic controller, and the at least one wireless communication unit is an external antenna component using fifth generation mobile communication technology.

In one of the possible or preferred embodiments, the electric control box further includes: a human-machine interface unit disposed on the box unit and connected to at least one of the control units, in which the human-machine interface unit is configured to generate and transmit at least one processing command to at least one of the control units by touch; and a wired communication unit connected to at least one of the control units, and at least one external device.

Therefore, in the gas valve cabinet provided by the present disclosure, by virtue of “the electrical control box including a first box unit, a plurality of control units, a plurality of substrate units and at least one wireless communication unit, the first box unit having a first accommodating space, the control units being disposed in the first accommodating space, the substrate units being respectively connected to one of the control units, the at least one wireless communication unit being disposed on the first box unit and connected to at least one of the control units, the gas valve box including a second box unit, a plurality of pipe units and a plurality of sensing units, the second box unit having a second accommodating space and being adjacent to the first box unit, the pipe units being disposed in the second accommodating space, at least one of the pipe units being disposed in the second box unit, the sensing units being disposed on the pipe units and connected to at least one of the control units, each sensing unit being configured to detect the flow rate or pressure of the gas transmitted by one of the pipe units to generate at least one sensing signal, and the at least one wireless communication unit being configured to transmit at least one sensing signal to at least one external device,” the present disclosure can improve practicality and convenience of the gas valve cabinet.

Furthermore, in the electrical control box provided by the present disclosure, by virtue of “the box unit having an accommodating space, the control units being disposed in the accommodating space, the substrate units being respectively connected to one of the control units, and the at least one wireless communication unit being disposed in the box unit and connected to at least one control unit,” the present disclosure can improve practicality and convenience of the gas valve cabinet.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a gas valve cabinet according to a first embodiment of the present disclosure;

FIG. 2 is another schematic perspective view of the gas valve cabinet according to the first embodiment of the present disclosure;

FIG. 3 is a partial schematic perspective view of an electrical control box according to the first embodiment of the present disclosure;

FIG. 4 is another partial schematic perspective view of the electrical control box according to the first embodiment of the present disclosure;

FIG. 5 is a schematic perspective view of the electrical control box according to the first embodiment of the present disclosure;

FIG. 6 is a partial schematic perspective view of a gas valve box according to the first embodiment of the present disclosure; and

FIG. 7 is a functional block diagram of the gas valve cabinet according to a second embodiment of the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

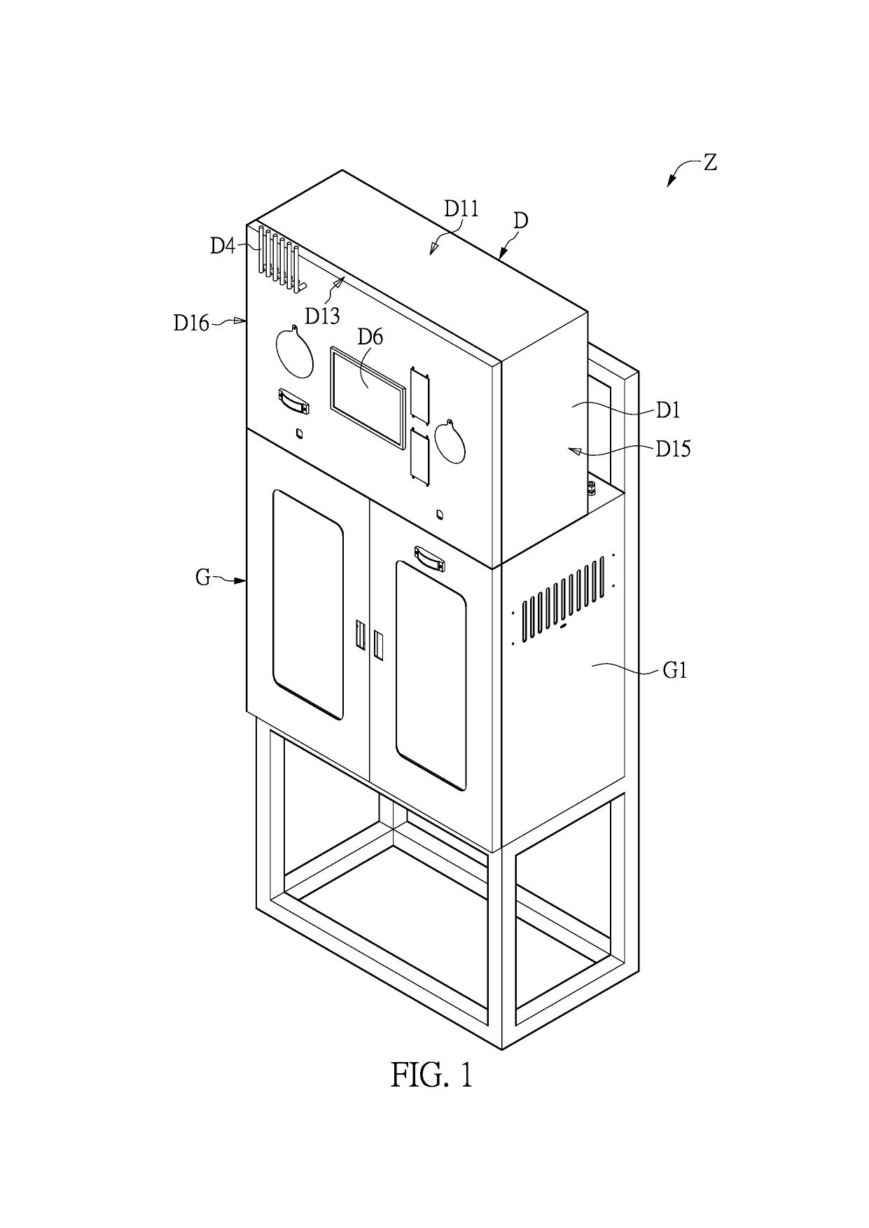

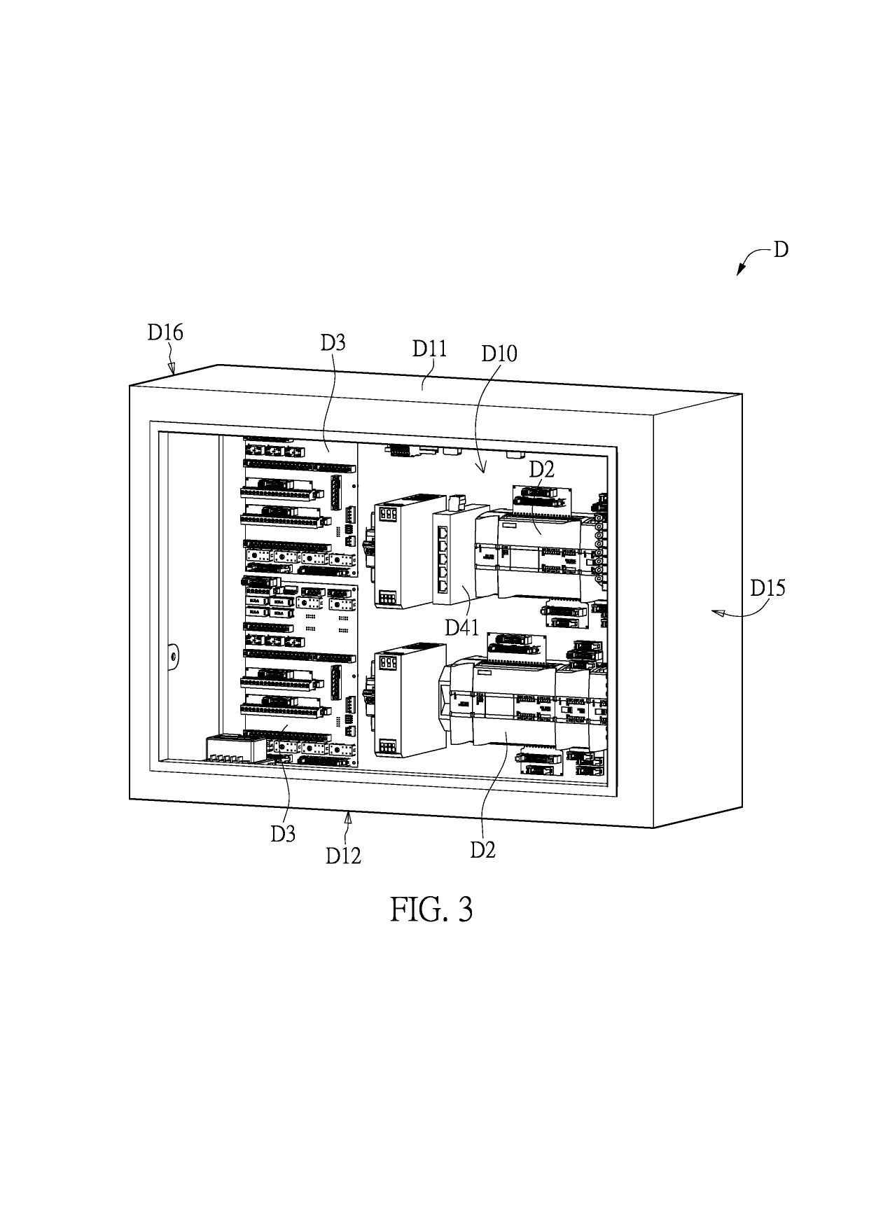

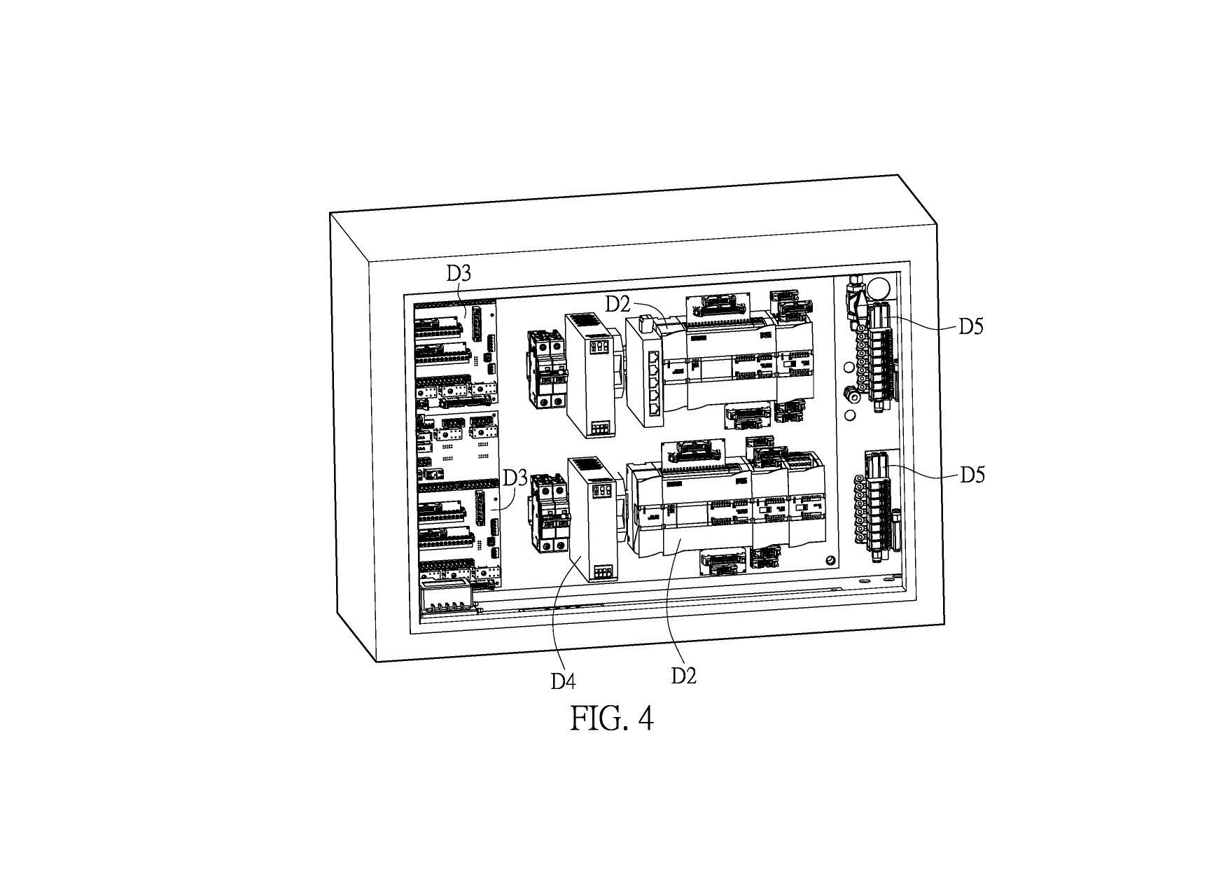

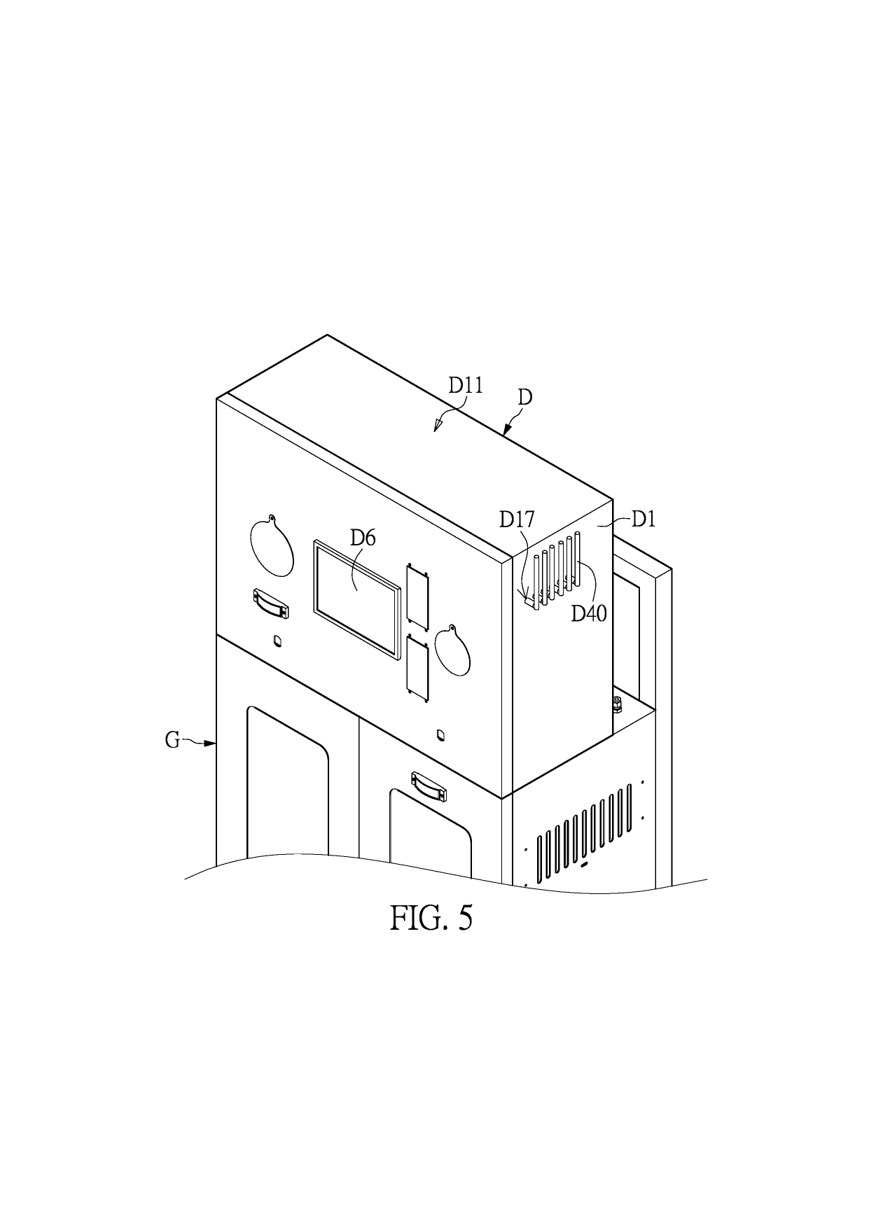

Referring to FIG. 1 to FIG. 6, which are a schematic perspective view of a gas valve cabinet, another schematic perspective view of the gas valve cabinet, a partial schematic perspective view of an electrical control box, another partial schematic perspective view of the electrical control box, a schematic perspective view of the electrical control box, and a partial schematic perspective view of a gas valve box, according to a first embodiment of the present disclosure, respectively. As shown in the above figures, the first embodiment of the present disclosure provides a gas valve cabinet Z (or a gas valve device), which may include an electrical control box D (or an electrical module) and a gas valve box G (or a gas valve module).

As shown in FIG. 1 to FIG. 5, the electrical control box D may include a first box unit D1, a plurality of control units D2, a plurality of substrate units D3 and at least one wireless communication unit D4.

For example, the first box unit D1 may be a detachable box structure. The first box unit D1 may have a first accommodating space D10 and a plurality of outer surfaces, and the first accommodating space D10 is defined between the outer surfaces. The outer surfaces may include a top surface D11, a bottom surface D12, a front side surface D13, a rear side surface D14, a left side surface D15, and a right side surface D16, in which the top surface D11 may be connected to the front side surface D13, the rear side surface D14, the left side surface D15 and the right side surface D16 and disposed opposite to the bottom surface D12, the front side surface D13 may be connected to the top surface D11, the bottom surface D12, the left side surface D15 and the right side surface D16 and disposed opposite to the rear side surface D14, and the left side surface D15 may be connected to the top surface D11, the bottom surface D12, the front side surface D13 and the rear side surface D14 and disposed opposite to the right side surface D16.

The control units D2 may be detachably disposed in the first accommodating space D10. Each control unit D2 may be a programmable logic controller (PLC). The substrate units D3 may be connected to one of the control units D2 respectively, in which each substrate unit D3 may be a printed circuit board (PCB).

The wireless communication unit D4 may be disposed on the first box unit D1 and connected to at least one control unit D2. The wireless communication unit D4 may be an external antenna component using fifth generation mobile communication technology (5th-Generation Mobile Communication Technology, 5G). The wireless communication unit D4 may be detachably disposed on one of the outer surfaces (i.e., the top surface D11, the bottom surface D12, the front side surface D13, the rear side surface D14, the left side surface D15 or the right side surface D16). Furthermore, the body of the first box unit D1 may have at least one through hole D17, the through hole D17 passes through the body of the first box unit D1 and corresponds to one of the outer surfaces, and the wireless communication unit D4 may detachably pass through the through hole D17 and be electrically connected to at least one control unit D2 through the through hole D17. Moreover, the wireless communication unit D4 may include an antenna element D40 and a communication element D41. The antenna element D40 may be a wireless antenna, and the antenna element D40 may be detachably disposed on one of the top surface D11, the bottom surface D12, the front side surface D13, the rear side surface D14, the left side surface D15 and the right side surface D16. The communication element D41 may be a communication host device, and the communication element D41 may be located in the first accommodating space D10 and adjacent to the top surface D11 and one of the control units D2, and the communication element D41 may be electrically connected to at least one of the control units D2.

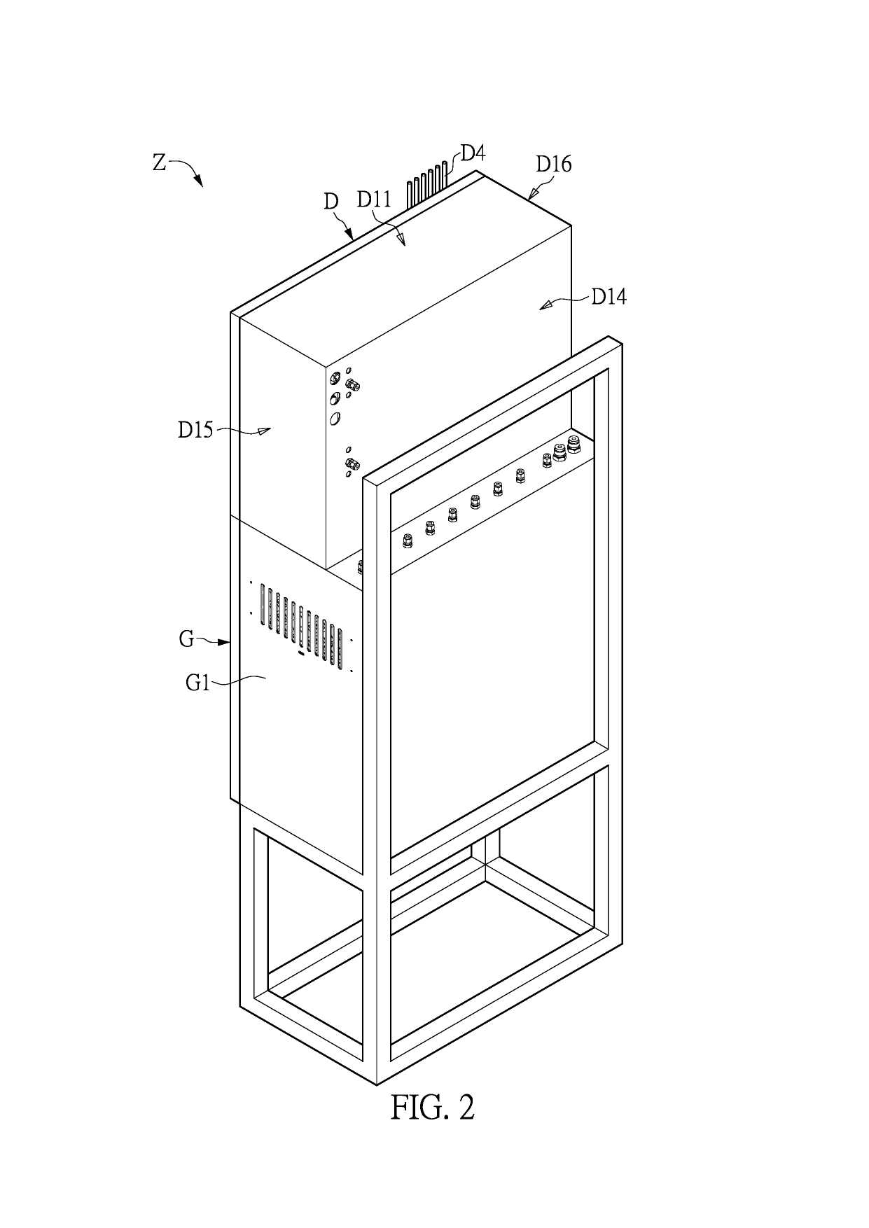

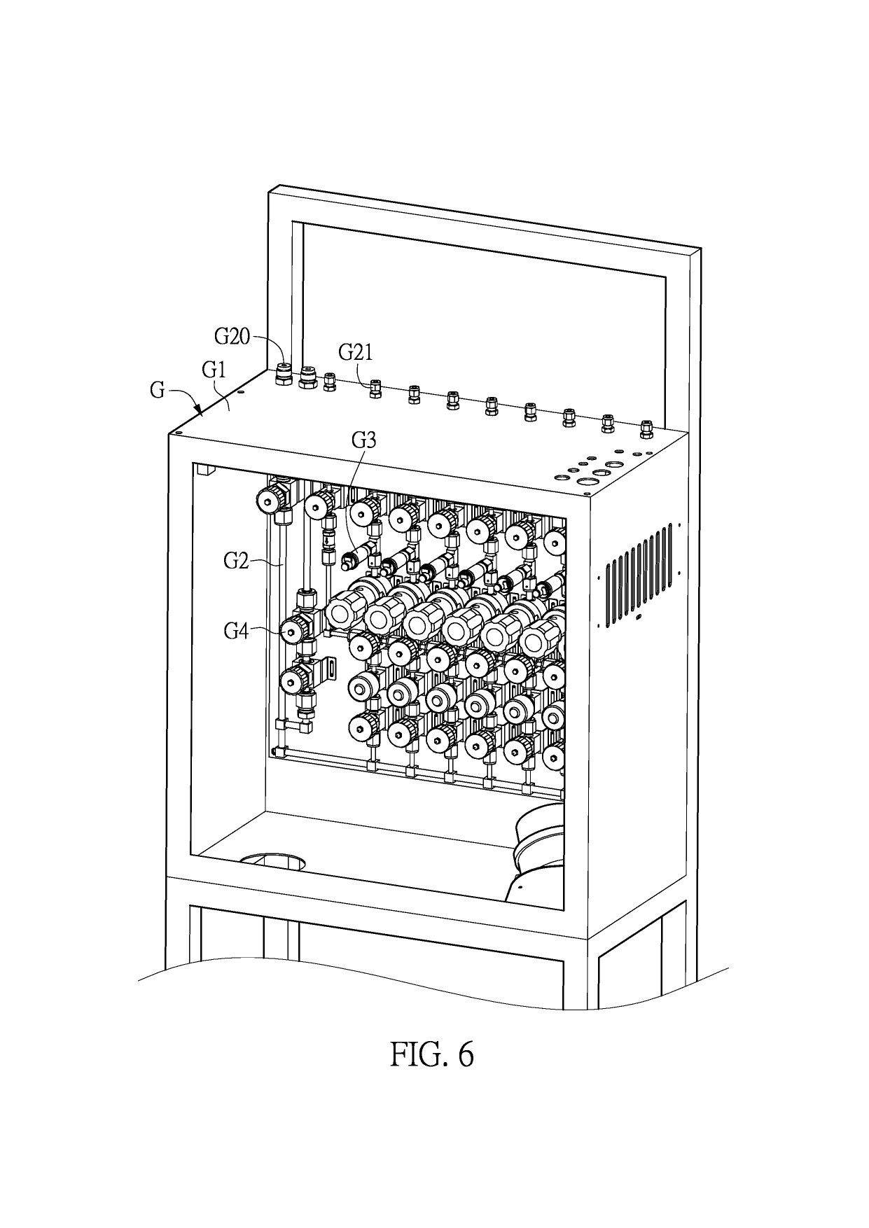

Next, as shown in FIG. 1, FIG. 2 and FIG. 6, the valve box G may include a second box unit G1, a plurality of pipe units G2 and a plurality of sensor units G3.

For example, the second box unit G1 may have a second accommodating space G10 and be adjacent to the first box unit D1. The second box unit G1 may be a detachable box structure, in which the structure of the second box unit G1 may be similar to that of the first box unit D1, and the volume of the second box unit G1 is larger than the first box unit D1, but not limited thereto.

The pipe units G2 may be disposed in the second accommodating space G10, and at least one pipe unit G2 can pass through the second box unit G1. Any one of the pipe units G2 may be connected and communicated with another one of the pipe units G2. At least one of the pipe units G2 may have an inlet portion G20, the inlet portion G20 may be configured to connect to an external gas supply (not shown in the figures) and receive the gas provided by the external gas supply, and the inlet portion G20 may be exposed outside the second box unit G1. In addition, a part of the pipe units G2 may have an outlet portion G21, the outlet portion G21 may be configured to connect to an external process device (not shown in the figures), and the outlet portion G21 may be exposed outside the second box unit G1. The sensing units G3 may be disposed on the pipe units G2 and connected to at least one control unit D2, and each sensing unit G3 may be configured to detect the flow rate or pressure of the gas transmitted by one of the pipe units G2 to generate at least one sensing signal. Each sensing unit G3 may be a flow sensing element of the pipe. The at least one wireless communication unit D4 may be configured to transmit at least one sensing signal to at least one external device E.

Referring to FIG. 1 to FIG. 6, when the gas valve cabinet Z of the present disclosure is in operation, at least one control unit D2 can communicate with an external device E (such as a central control center, monitoring equipment or other process equipment, but not limited thereto) through a wireless communication unit D4. Therefore, the control unit D2 can receive the sensing signal of the sensing unit G3, the sensing signal can be transmitted to the antenna element D40 through the communication element D41 of the wireless communication unit D4, and then the antenna element D40 can be used to send (transmit) the sensing signal to at least one external device E, so that the external device or other operators can obtain the operating status of the gas valve cabinet Z in real time. It is worth mentioning that in other optional embodiments, when the control unit D2 determines that the sensing signal detected by the sensing unit G3 is abnormal, the control unit D2 can generate at least one abnormal signal accordingly, and can transmit at least one abnormal signal to at least one external device E through the wireless communication unit D4, so that the external device E or other operators can know the abnormal status of the gas valve cabinet Z in real time.

Furthermore, when the gas valve cabinet Z of the present disclosure is in operation, one of the control units D2 can be in operation and transmit at least one operation signal to another control unit D2 (which is in standby state). When one of the control units D2 fails or is abnormal, another control unit D2 can take over the faulty or abnormal control unit D2 to perform the current operation (such as receiving and transmitting sensing signals). At the same time, at least one abnormal signal can be generated and transmitted to at least one external device E through the wireless communication unit D4, so that the external device E or other operators can know the abnormal status of the control unit D2 in real time.

Therefore, the gas valve cabinet Z of the present disclosure can use the wireless communication unit D4 of the fifth generation mobile communication technology through the above-mentioned technical solution, so that the control unit D2 can send (transmit) the sensing signal to the external device E by wireless transmission, and the external device E or other operators can obtain the operating status of the gas valve cabinet Z in real time, thereby improving the practicality of the gas valve cabinet Z and achieving the convenience of information transmission. In addition, the transmission cable can be omitted, thereby saving the cost of equipment construction and increasing the flexibility of the location setting of the gas valve cabinet Z.

Furthermore, the electrical control box D of the present disclosure may also include a plurality of driving units D5 and a plurality of valve units G4. The driving units D5 are disposed in the first accommodating space D10, and the driving units D5 are connected to one of the control units D2. The valve units G4 are disposed in the second accommodating space G10 and respectively connected to the pipe units G2, and the valve units G4 are connected to the driving units D5, and each of the valve units G4 is configured to control the opening and closing of one of the pipe units G2 for transmitting gas.

For example, as shown in FIG. 1 to FIG. 6, the driving units D5 may be located in the first accommodating space D10, and each of the driving units D5 may be electrically connected to at least one control unit D2, in which the driving unit D5 may be a solenoid valve or other types of control valve components, the valve units G4 may be connected to the pipe units G2 and at least one control unit D2, and the valve unit G4 may be a flow control valve. Therefore, one of the control units D2 can control at least one driving unit D5 to operate according to the operating state (such as open, closed and abnormal status, but not limited thereto) of the gas valve cabinet Z, so that the driving unit D5 can drive the corresponding valve unit G4 to open or close, and then drive the gas in the pipe unit G2 to be transmitted or stopped.

It is worth noting that in other optional embodiments, the user can also send (transmit) a control signal to the electrical control box D through a computer or a mobile phone in a wireless network transmission mode, and the electrical control box D can receive the control signal (i.e., the external signal) through the wireless communication unit D4. Then, the control unit D2 can control the valve unit G4 to operate by controlling the driving unit D5 according to the control signal, so that the gas provided by the external gas supply can be transmitted to the external process device matched with the outlet portion G21 through at least one pipe unit G2 and at least one outlet portion G21, or stop supplying gas to the external process device. Therefore, the gas valve cabinet Z of the present disclosure can also provide the user with a method of wirelessly transmitting a control signal to the gas valve cabinet Z to drive the control unit D2 and the sensing unit G3 to operate, thereby improving the convenience of operation.

Furthermore, the electrical control box D of the present disclosure may also include a human-machine interface unit D6. The human-machine interface unit D6 may be disposed on the first box unit D1 and connected to at least one control unit D2. The human-machine interface unit D6 may be configured to generate at least one processing command and transmit the at least one processing command to at least one control unit D2 through user touch.

For example, as shown in FIG. 1, the human-machine interface unit D6 may be a touch-screen electronic device (or a touch-sensitive electronic device), which may be embedded in the front side surface D13 of the first box unit D1, but is not limited thereto. Therefore, the user can also use the human-machine interface unit D6 to generate control instructions (i.e., a processing command) by touching and operating the human-machine interface unit D6. Then, the control unit D2 may control at least one sensing unit G3 to be turned on or off according to the control instruction, so that the gas provided by the external gas supply may be transmitted to the external process device matched with the outlet portion G21 through at least one pipe unit G2 and at least one outlet portion G21.

In addition, according to the above content, referring to FIG. 1 to FIG. 5, the present disclosure further provides an electrical control box D, which may include a box unit (i.e., a first box unit D1), a plurality of control units D2, a plurality of substrate units D3, and at least one wireless communication unit D4. The box unit may have an accommodating space (i.e., a first accommodating space D10). The control units D2 may be disposed in the accommodating space. The substrate units D3 may be respectively connected to one of the control units D2. The at least one wireless communication unit D4 may be disposed in the box unit and connected to at least one control unit D2. In addition, the electrical control box D may be applied to the above-mentioned gas valve cabinet Z.

However, the above-mentioned example is only one of the feasible embodiments and is not intended to limit the present disclosure.

### Second embodiment

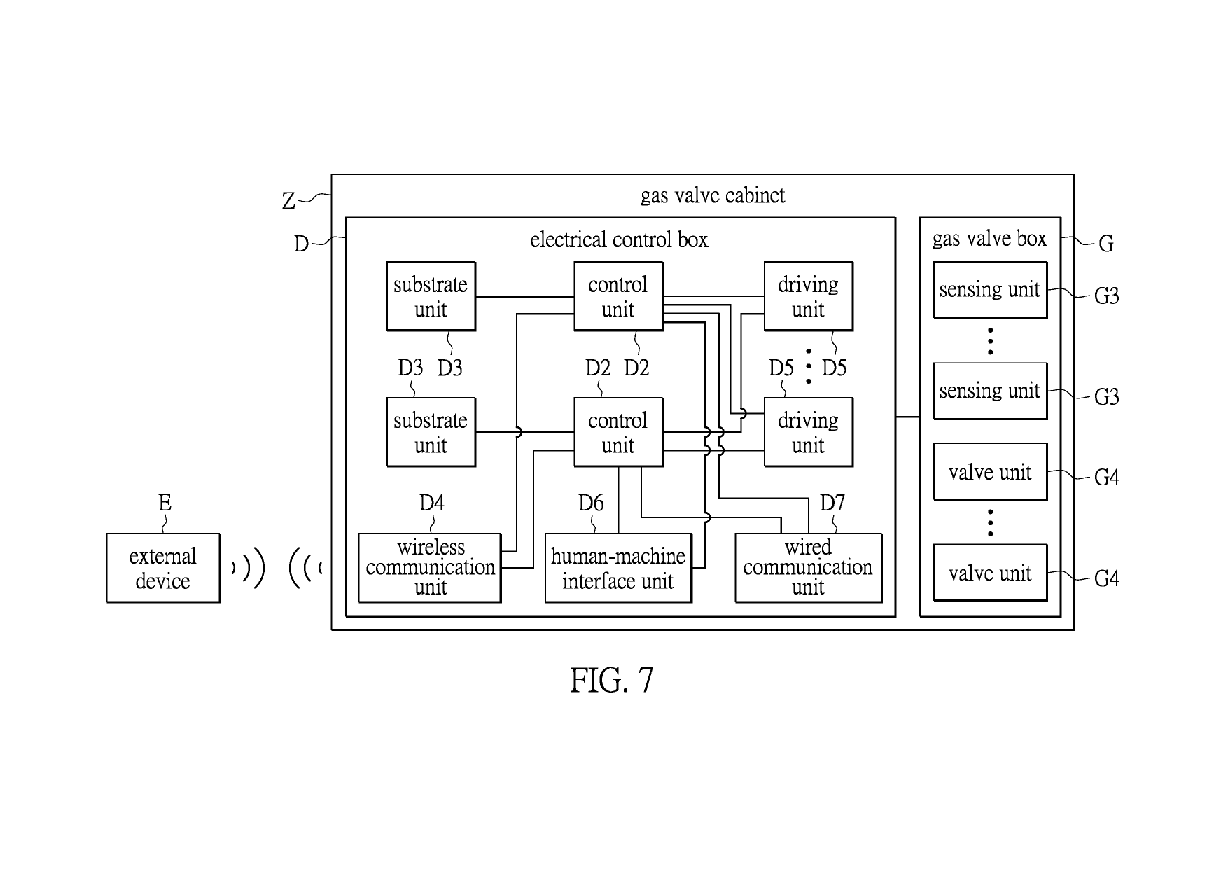

Refer to FIG. 7, which is a functional block diagram of the gas valve cabinet of the second embodiment of the present disclosure, and refer to FIG. 1 to FIG. 6 together. As shown in the FIG. 1 to FIG. 7, the gas valve cabinet Z of the second embodiment is roughly similar to the gas valve cabinet Z of the first embodiment, so the setting or actuation of the same components will not be repeated here. The difference between the second embodiment and the first embodiment is that, in the second embodiment, the electrical control box D may also include a wired communication unit D7. The wired communication unit D7 can be connected to at least one control unit D2 and at least one external device E.

For example, as shown in FIG. 7, the wired communication unit D7 may be a network interface controller (NIC) or other types of wired network cards. The wired communication unit D7 may be disposed in the first accommodating space D10 of the first box unit D1, and the wired communication unit D7 may be connected to the external device E through a transmission wire (such as a network cable).

Therefore, after receiving the sensing signal of the sensing unit G3, the control unit D2 may transmit the sensing signal to at least one external device E through the wired communication unit D7, so that the external device E or other operators can obtain the operating status of the gas valve cabinet Z in real time. Correspondingly, when the control unit D2 generates at least one abnormal signal, the at least one abnormal signal can also be transmitted to at least one external device E through the wired communication unit D7.

It is worth noting that in other optional embodiments, the user can also send (transmit) a control signal to the electrical control box D through a computer via a wired network transmission, and the electrical control box D can receive the control signal (i.e., the external signal) through the wired communication unit D7. Then, the control unit D2 can control the valve unit G4 to operate by controlling the driving unit D5 according to the control signal, so that the gas provided by the external gas supply can be transmitted to the external process device matched with the outlet portion G21 through at least one pipe unit G2 and at least one outlet portion G21, or stop supplying gas to the external process device.

Therefore, the gas valve cabinet Z of the present disclosure can not only use the wireless communication unit D4 to send (transmit) the sensing signal to the external device E in a wireless manner, but also transmit the sensing signal to the external device E in a wired manner through the wired communication unit D7 through the above-mentioned technical solution, thereby improving the practicality of the gas valve cabinet Z.

### Beneficial Effects of the Embodiments

In conclusion, in the gas valve cabinet Z provided by the present disclosure, by virtue of “the electrical control box D including a first box unit D1, a plurality of control units D2, a plurality of substrate units D3 and at least one wireless communication unit D4, the first box unit D1 having a first accommodating space D10, the control units D2 being disposed in the first accommodating space D10, the substrate units D3 being respectively connected to one of the control units D2, the at least one wireless communication unit D4 being disposed on the first box unit D1 and connected to at least one of the control units D2, the gas valve box G including a second box unit G1, a plurality of pipe units G2 and a plurality of sensing units G3, the second box unit G1 having a second accommodating space G10 and being adjacent to the first box unit D1, the pipe units G2 being disposed in the second accommodating space G10, at least one of the pipe units G2 being disposed in the second box unit G1, the sensing units G3 being disposed on the pipe units G2 and connected to at least one of the control units D2, each sensing unit G3 being configured to detect the flow rate or pressure of the gas transmitted by one of the pipe units G2 to generate at least one sensing signal, and the at least one wireless communication unit D4 being configured to transmit at least one sensing signal to at least one external device E,” the present disclosure can improve practicality and convenience of the gas valve cabinet Z.

Furthermore, in the electrical control box D provided by the present disclosure, by virtue of “the box unit having an accommodating space, the control units D2 being disposed in the accommodating space, the substrate units D3 being respectively connected to one of the control units D2, and the at least one wireless communication unit D4 being disposed in the box unit and connected to at least one control unit D2,” the present disclosure can improve practicality and convenience of the gas valve cabinet Z.

Moreover, the gas valve cabinet Z of the present disclosure can use the above-mentioned technical solution to set up a wireless communication unit D4 using the fifth-generation mobile communication technology, so that the user can send (transmit) a control signal to the gas valve cabinet Z by wireless transmission to drive the control unit D2 and the sensing unit G3 to operate, thereby achieving convenient operation. In addition, the transmission wire can be omitted, thereby saving the cost of equipment construction and improving the flexibility of the position setting of the gas valve cabinet Z. Moreover, the gas valve cabinet Z of the present disclosure can not only use the wireless communication unit D4 to receive the control signal sent by the user in a wireless manner, but also use the wired communication unit D7 to receive the control signal sent by the user in a wired manner, thereby improving the practicality of the gas valve cabinet Z.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A gas valve cabinet, comprising:
an electric control box, comprising:
a first box unit having a first accommodating space;
a plurality of control units disposed in the first accommodating space;
a plurality of substrate units respectively connected to one of the control units; and
at least one wireless communication unit disposed on the first box unit and connected to at least one of the control units; and
a gas valve box, comprising:
a second box unit having a second accommodating space and adjacent to the first box unit;
a plurality of pipe units disposed in the second accommodating space, wherein at least one of the pipe units passes through the second box unit; and
a plurality of sensing units disposed on the pipe units and connected to at least one of the control units, wherein each of the sensing units is configured to detect a flow rate or a pressure of a gas transmitted by one of the pipe units to generate at least one sensing signal;
wherein the at least one wireless communication unit is configured to transmit the at least one sensing signal to at least one external device.

2. The gas valve cabinet according to claim 1,
wherein the first box unit has a plurality of outer surfaces, the first accommodating space is defined by the outer surfaces, and the at least one wireless communication unit is disposed on one of the outer surfaces;
wherein each of the control units is a programmable logic controller; and
wherein the at least one wireless communication unit is an external antenna component using fifth generation mobile communication technology.

3. The gas valve cabinet according to claim 2,
wherein the outer surfaces include a top surface, a bottom surface, a front side surface, a rear side surface, a left side surface and a right side surface, the top surface is connected to the front side surface, the rear side surface, the left side surface and the right side surface and is disposed opposite to the bottom surface, the front side surface is connected to the top surface, the bottom surface, the left side surface and the right side surface and is disposed opposite to the rear side surface, and the left side surface is connected to the top surface, the bottom surface, the front side surface and the rear side surface and is disposed opposite to the right side surface; and
wherein the at least one wireless communication unit is disposed on one of the top surface, the bottom surface, the front side surface, the rear side surface, the left side surface and the right side surface.

4. The gas valve cabinet according to claim 1, wherein the electric control box further comprises:
a plurality of driving units disposed in the first accommodating space and connected to one of the control units; and
a plurality of valve units disposed in the second accommodating space and respectively connected to the pipe units, wherein the valve units are connected to the driving units, and each of the valve units is configured to control one of the pipe units for transmitting the gas.

5. The gas valve cabinet according to claim 1, wherein the electric control box further comprises:
a human-machine interface unit disposed on the first box unit and connected to at least one of the control units, wherein the human-machine interface unit is configured to generate and transmit at least one processing command to at least one of the control units by touch; and
a wired communication unit connected to at least one of the control units, and at least one external device.

6. An electric control box, comprising:
a box unit having an accommodating space;
a plurality of control units disposed in the accommodating space; and
a plurality of substrate units respectively connected to one of the control units.

7. The electric control box according to claim 6, wherein the box unit has a plurality of outer surfaces, the accommodating space is defined by the outer surfaces, and the at least one wireless communication unit is disposed on one of the outer surfaces.

8. The electric control box according to claim 7,
wherein the outer surfaces include a top surface, a bottom surface, a front side surface, a rear side surface, a left side surface and a right side surface, the top surface is connected to the front side surface, the rear side surface, the left side surface and the right side surface and is disposed opposite to the bottom surface, the front side surface is connected to the top surface, the bottom surface, the left side surface and the right side surface and is disposed opposite to the rear side surface, and the left side surface is connected to the top surface, the bottom surface, the front side surface and the rear side surface and is disposed opposite to the right side surface; and
wherein the at least one wireless communication unit is disposed on one of the top surface, the bottom surface, the front side surface, the rear side surface, the left side surface and the right side surface.

9. The electric control box according to claim 6,
wherein each of the control units is a programmable logic controller; and
wherein the at least one wireless communication unit is an external antenna component using fifth generation mobile communication technology.

10. The electric control box according to claim 6, wherein the electric control box further comprises:
a human-machine interface unit disposed on the box unit and connected to at least one of the control units, wherein the human-machine interface unit is configured to generate and transmit at least one processing command to at least one of the control units by touch; and
a wired communication unit connected to at least one of the control units, and at least one external device.
